(19) United States
(12) Patent Application Publication
(10) Pub. No.: US 2015/0028297 A1
(43) Pub. Date: Jan. 29, 2015

(54) FACING TARGETS SPUTTERING APPARATUS, ORGANIC LIGHT-EMITTING DISPLAY APPARATUS MANUFACTURED USING THE FACING TARGETS SPUTTERING APPARATUS, AND METHOD FOR MANUFACTURING THE ORGANIC LIGHT-EMITTING DISPLAY APPARATUS

(71) Applicant: Samsung Display Co., Ltd., Yongin-City (KR)

(72) Inventors: Su-Hyuk CHOI, Yongin-City (KR); Hun KIM, Yongin-City (KR); Jin-Woo PARK, Yongin-City (KR)

(73) Assignee: Samsung Display Co., Ltd., Yongin-City (KR)

(21) Appl. No.: 14/159,800

(22) Filed: Jan. 21, 2014

(30) Foreign Application Priority Data
Jul. 25, 2013 (KR) 10-2013-0088176

(51) Int. Cl. C23C 14/35; H01L 51/56; H01L 51/52

(52) U.S. Cl. CPC C23C 14/352; H01L 51/5237; H01L 51/56
USPC 257/40; 204/298.07; 204/192.25

(57) ABSTRACT

A sputtering apparatus, an organic light-emitting display apparatus manufactured using the sputtering apparatus, and a method for manufacturing the organic light-emitting display apparatus are provided. The sputtering apparatus includes: a chamber including a mounting portion configured to hold a deposition target material; a gas supply unit that faces the mounting portion and supplies gas to the chamber; a first target portion and a second target portion that are disposed to face each other within the chamber; and a magnetic field induction coil that surrounds an outside of the chamber.

### RELATED APPLICATIONS

This application claims the benefit of Korean Patent Application No. 10-2013-0088176, filed on Jul. 25, 2013, in the Korean Intellectual Property Office, the disclosure of which is incorporated herein in its entirety by reference.

### BACKGROUND

1. Field

A facing targets sputtering apparatus, an organic light-emitting display apparatus manufactured using the facing targets sputtering apparatus, and a method for manufacturing the organic light-emitting display apparatus, are provided. More particularly, a facing targets sputtering apparatus capable of manufacturing an organic light-emitting display apparatus having excellent characteristics, an organic light-emitting display apparatus manufactured using the facing targets sputtering apparatus, and a method for manufacturing the organic light-emitting display apparatus are provided.

2. Description of the Related Art

An organic light-emitting display apparatus is a self-luminous display apparatus which includes a plurality of organic light-emitting devices each including a hole injection electrode, an electron injection electrode, and an organic emission layer provided therebetween. An exciton is generated when a hole injected from the hole injection electrode is recombined with an electron injected from the electron injection electrode within the organic emission layer. Light is emitted when the exciton falls from an excited state to a ground state.

Because the organic light-emitting display apparatus is a self-luminous display apparatus, a separate light source is unnecessary. Therefore, the organic light-emitting display apparatus may be driven at a low voltage, and may be manufactured to have a light weight and a slim profile. In addition, the organic light-emitting display apparatus has highly desirable characteristics, such as a wide viewing angle, a high contrast, and a fast response time. Therefore, the organic light-emitting display apparatus is considered as a next-generation display apparatus.

Because the organic light-emitting device is vulnerable to the external environment, for example, oxygen or moisture, there is a need for a sealing structure that seals the organic light-emitting device from the external environment.

A sputtering method is one of a number of film formation technologies that may be used in a process of manufacturing the organic light-emitting display apparatus. The sputtering method is widely known as a dry process technology having a broad scope of application. In the sputtering method, inert gas, such as argon gas, is introduced into a vacuum vessel, and a film is formed by supplying DC power or RF power to a cathode provided with a sputtering target.

A magnetron-type sputtering method, in which a substrate and a target face each other, is commonly used. However, in the magnetron-type sputtering method, secondary electrons released from a surface of the target or sputtered particles having high kinetic energy collide against an organic layer or an inorganic layer stacked on an organic light-emitting device. Thus, the organic layer or the inorganic layer may be physically damaged during the process. Consequently, characteristics of the organic light-emitting device may be degraded.

### SUMMARY

A facing targets sputtering apparatus, which is capable of improving a thin-film deposition rate, an organic light-emitting display apparatus using the facing targets sputtering apparatus, and a method for manufacturing the organic light-emitting display apparatus are provided.

Additional aspects will be set forth in part in the description which follows and, in part, will be apparent from the description.

A sputtering apparatus includes: a chamber including a mounting portion configured to hold a deposition target material; a gas supply unit that faces the mounting portion and supplies gas to the chamber; a first target portion and a second target portion that face each other within the chamber; and a magnetic field induction coil that surrounds an outside of the chamber.

The first target portion and the second target portion may be separated from each other, an the gas supply unit is positioned so that gas supplied from the gas supply unit passes through a gap between the first target portion and the second target portion.

The magnetic field induction coil may be provided at a position corresponding to positions of the first target portion and the second target portion.

Each of the first target portion and the second target portion may include: a target plate on which a sputtering target is mounted; a yoke disposed on a rear surface of the target plate; and a magnetic field generator disposed on a rear surface of the yoke.

The magnetic field generator may include: a first magnetic field generator; and a second magnetic field generator, wherein the first magnetic field generator and the second magnetic field generator are disposed at both ends of the yoke.

The magnetic field generator may further include a third magnetic field generator, wherein the third magnetic field generator is disposed in a center of the target plate and generates a magnetic field in an opposite direction to a magnetic field generated by the first and second magnetic field generators.

The yoke may be made of a ferromagnetic material or a paramagnetic material.

The yoke may be made of one of iron, cobalt, nickel, and an alloy thereof.

A pressure of sputtering gas between the first target portion and the second target portion may be in the range of about 0.1 mTorr to about 100 mTorr.

The mounting portion may further include a temperature controller that controls a temperature of the deposition target material.

An organic light-emitting display apparatus includes: a substrate; an organic emission portion including an organic light-emitting device on the substrate; and an encapsulating film that seals the organic emission portion, the encapsulating film being formed using the sputtering apparatus.

The encapsulating film may include a low temperature viscosity transition (LVT) inorganic material.

The encapsulating film may include tin oxide.

The encapsulating film may include an LVT inorganic material, and a viscosity transition temperature of the LVT inorganic material is lower than a metamorphic temperature of the organic emission portion.

A method for manufacturing an organic light-emitting display apparatus includes: preparing a deposition target material in which an organic emission portion is formed on a substrate; and forming an encapsulating film to seal the organic emission portion by using a sputtering apparatus, wherein the sputtering apparatus includes: a chamber including a mounting portion holding the deposition target; a gas supply unit facing the mounting portion and supplying gas to the chamber; a first target portion and a second target portion facing each other within the chamber; and a magnetic field induction coil surrounding an outside of the chamber.

The forming of the encapsulating film may include: depositing a preliminary encapsulating film to cover the organic emission portion; and performing an annealing process on the preliminary encapsulating film.

The encapsulating film may include an LVT inorganic material.

The facing targets sputtering apparatus may further include a temperature controller that controls a temperature of the deposition target material, and an annealing process may be performed on the encapsulating film by the temperature controller.

The annealing process may be performed at a lower temperature than a metamorphic temperature of a material included in the organic emission portion.

The annealing process may be performed under a vacuum atmosphere or an inert gas atmosphere.

### BRIEF DESCRIPTION OF THE DRAWINGS

These and/or other aspects will become apparent and more readily appreciated from the following description of the embodiments, taken in conjunction with the accompanying drawings of which:

FIG. 1 is a schematic diagram of a facing targets sputtering apparatus according to an embodiment;

FIG. 2A is a diagram of a sputtering target portion according to an embodiment;

FIG. 2B is a diagram of a sputtering target portion according to another embodiment;

FIGS. 3A to 3C are cross-sectional views describing a method for manufacturing an organic light-emitting display apparatus 200 using the facing targets sputtering apparatus 1 according to an embodiment; and

FIG. 4 is a partial cross-sectional view illustrating an example of a portion I of FIG. 3C.

FIG. 5 illustrates a process for manufacuting an organic light-emitting display apparatus using the faccting targets sputtering apparatus 1 according to an embodiment.

### DETAILED DESCRIPTION

Reference will now be made in detail to various embodiments, examples of which are illustrated in the accompanying drawings, in which like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The embodiments set forth herein are merely examples, and various modifications may be made from these embodiments. For example, it will be understood that when a layer, region, or component is referred to as being “formed on,” another layer, region, or component, it can be directly or indirectly formed on the other layer, region, or component. That is, for example, intervening layers, regions, or components may be present.

The terms used in the present specification are merely used to describe particular embodiments, and are not intended to limit the present invention. As used herein, the singular forms “a,” “an” and “the” are intended to include the plural forms as well, unless the context clearly indicates otherwise. It will be further understood that the terms “comprises” and/or “comprising” used herein specify the presence of stated features or components, but do not preclude the presence or addition of one or more other features or components. It will be understood that although the terms “first”, “second”, etc. may be used herein to describe various components, these components should not be limited by these terms. These components are only used to distinguish one component from another.

When a certain embodiment may be implemented differently, a specific process order may be performed differently from the described order. For example, two consecutively described processes may be performed substantially at the same time or performed in an order opposite to the described order.

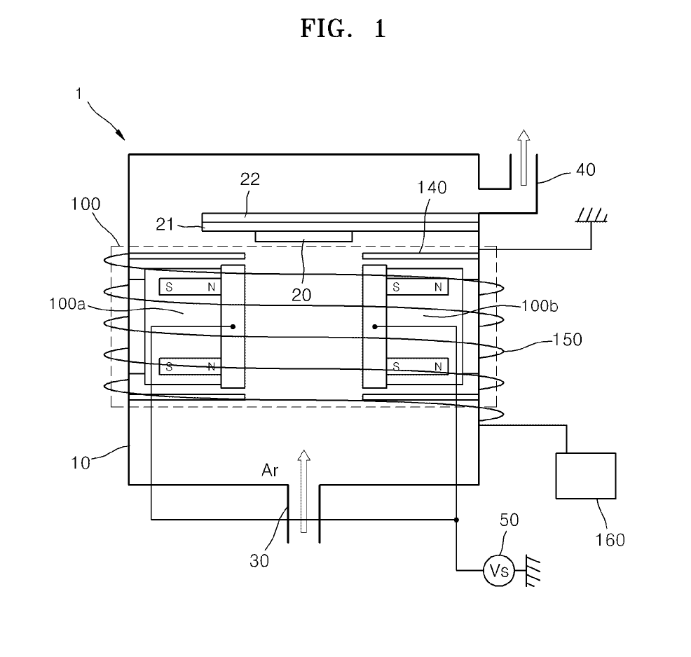

FIG. 1 is a schematic diagram of a facing targets sputtering apparatus 1 according to an embodiment.

Referring to FIG. 1, the facing targets sputtering apparatus 1 includes a chamber 10 with a mounting portion 21 on which a deposition target material 20 is to be mounted, a gas supply unit 30 that supplies gas to the chamber 10, a first target portion 100a and a second target portion 100b disposed to face each other, and a magnetic field induction coil 150 disposed to surround the outside of the chamber 10. The facing targets sputtering apparatus 1 may further include a target shielding portion 140, an exhaust port 40, and a sputtering power supply 50.

The chamber 10 is a vacuum chamber, and the inside of the chamber 10 may maintain a pressure of about 0.1 mTorr to about 100 mTorr.

The mounting portion 21 holds the deposition target material 20 and fixes the deposition target material 20 during film formation. The mounting portion 21 may include a temperature controller 22 that controls a temperature of the deposition target material 20. The temperature controller 22 may maintain the temperature of the deposition target material 20 according to the conditions required for film formation, and increase or maintain the temperature for an annealing process to be described below.

The gas supply unit 30 is disposed so as to face the mounting portion 21 and supplies gas to the inside of the chamber 10. The gas supply unit 30 may supply an inert gas such as argon (Ar) gas or various gases necessary for film formation, so as to stably and effectively generate plasma during a sputtering process. In addition, the gas supply unit 30 is disposed so as to face the mounting portion 21 and may direct the flow of plasma ions, atoms and gases inside the chamber 10 toward the deposition target material 20, for instance by having gas entering the interior of the chamber 10 enter through an inlet of the gas supply unit 30 that faces the mounting portion 21. The flow rate of the gas, for example argon gas, may be, for example, in the range of 80 to 100 sccm.

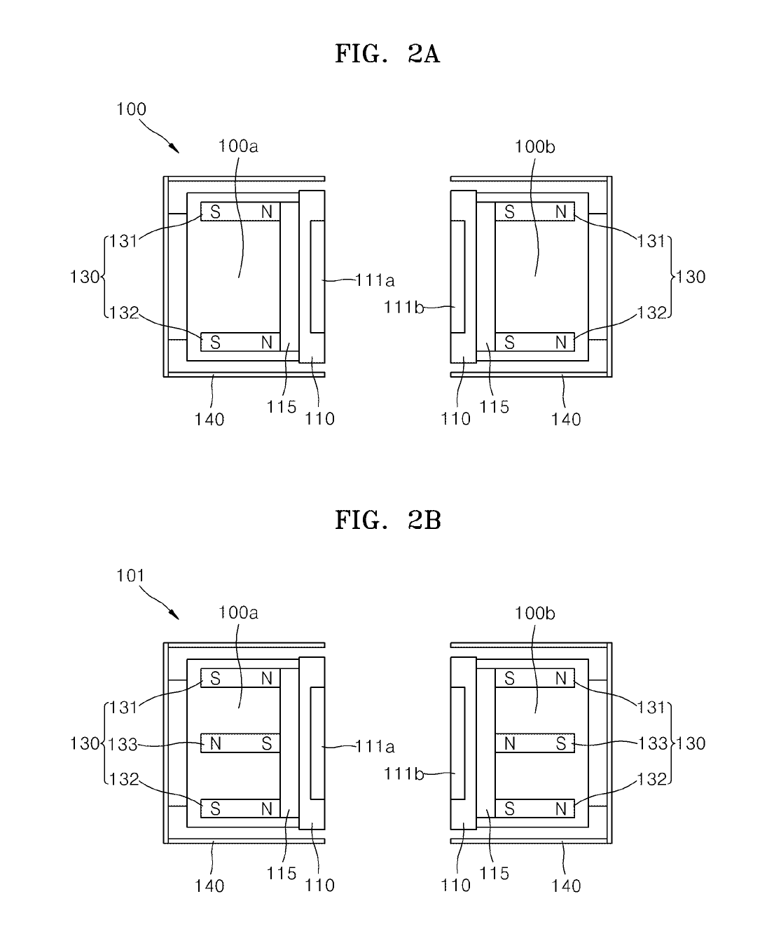

The sputtering target portion 100 includes a pair of target portions 100a and 100b that face each other. A configuration of the sputtering target portion 100 will be described below with reference to FIGS. 2A and 2B.

The magnetic field induction coil 150 is positioned so that it surrounds the outside of the chamber 10. The magnetic field induction coil 150 may be disposed in a position that corresponds to the position of the sputtering target portion 100.

When potential from an RF power supply 160 is applied to the magnetic field induction coil 150, an induced magnetic field is generated inside the chamber 10. Accordingly, a secondary induced current may be formed inside the chamber 10 by plasma ions or the like, and high-density plasma may be generated.

On the other hand, because the magnetic field induction coil 150 is disposed outside of the chamber 10, performance degradation may be prevented, and maintenance may be simplified. In other words, because the magnetic field induction coil 150 is disposed outside of the chamber 10, it is not likely that sputter materials will be coated on the coil by the sputtering or that the coil will be damaged by plasma. Additionally, accessibility for performing maintenance may be improved.

The target shielding portion 140 may protect the first target portion 100a and the second target portion 100b. In other words, the target shielding portion 140 may protect portions other than front surfaces of sputtering targets 111a and 111b (see FIG. 2A) from being sputtered. In addition, the target shielding portion 140 may serve as a ground.

The exhaust port 40 exhausts gas or the like from the chamber 10. The sputtering power supply 50 supplies sputtering power to the apparatus by using the target shielding portion 140 as an anode (ground) and the sputtering targets 111a and 111b (FIG. 2A) as a cathode. The power supplied from the sputtering power supply 50 may be a DC voltage or an AC voltage.

In one example, the size of deposition target material 20 may be about 1000×1200 mm and separation distances between the center of the target portions 100a and 100b and the center of the target material 20 is in the range of 50 to 100 mm. The strength of the magnetic fields on the surface of the sputtering targets 111a or 111b may be, for example, about 500 Gauss.

FIG. 2A is a diagram of the sputtering target portion 100 according to an embodiment.

Referring to FIG. 2A, the sputtering target portion 100 includes a pair of target portions—first target portion 100a and second target portion 100b. The first target portion 100a and the second target portion 100b may include target plates 110, on which the sputtering targets 111a and 111b are mounted, respectively, yokes 115 disposed on rear surfaces of the target plates 110, and magnetic field generators 130 disposed on rear surfaces of the yokes 115.

The sputtering targets 111a and 111b are mounted on the target plates 110 and are disposed so as to face each other at the first target portion 100a and the second target portion 100b. In addition, the sputtering targets 111a and 111b are made of a material intended to be formed on the deposition target material 20. The first sputtering target 111a and the second sputtering target 111b may be made of the same material or different materials, depending on the type of material to be formed on the deposition target material 20.

The magnetic field generators 130 generate a magnetic field in a space between the faced sputtering targets 111a and 111b of the first target portion 100a and the second target portion 100b. The magnetic field generators 130 of the first target portion 100a and the second target portion 100b are disposed with different polarities.

A plurality of magnetic field generators 130 may be provided. In some embodiments, the magnetic field generator 130 may include a first magnetic field generator 131 and a second magnetic field generator 132. The first magnetic field generator 131 and the second magnetic field generator 132 may, for example, be disposed at both ends of the yoke 115.

The yoke 115 makes the magnetic field generated from the magnetic field generator 130 uniform. To this end, the yoke 115 may be made of a material that may be made magnetic by the magnetic field generator 130. In other words, the yoke 115 may be made of a ferromagnetic material or a paramagnetic material. In some embodiments, the yoke 115 may be made, for example, of any one of iron, cobalt, nickel, and an alloy thereof.

FIG. 2B is a diagram of a sputtering target portion 101 according to another embodiment of the present invention. In FIG. 2B, the same reference numerals as those used in FIG. 2A refer to the same members, and a redundant description thereof will be omitted for conciseness.

Referring to FIG. 2B, the sputtering target portion 101 differs from the sputtering target portion 100 of FIG. 2A in that a magnetic field generator 130 of a sputtering target portion 101 further includes a third magnetic field generator 133.

The third magnetic field generator 133 is disposed in the center of the target plate 110. The third magnetic field generator 133 may generate a magnetic field in an opposite direction to those generated by the first and second magnetic field generators 131 and 132.

The above configuration of the magnetic field generator 130 may increase plasma that is confined between the first sputtering target 111a and the second sputtering target 111b. Accordingly, the usage rate of the sputtering targets 111a and 111b may be increased.

The operations of the facing targets sputtering apparatuses 1 according to embodiments are as follows.

Referring to FIG. 1, the deposition target material 20 is mounted on the mounting portion 21 of the chamber 10, and a sputtering gas such as argon (Ar) gas is supplied through the sputtering gas supply unit 30 into the space between the first target portion 100a and the second target portion 100b.

When a material formed on the deposition target material 20 by the facing targets sputtering apparatus 1 according to the embodiments is an oxygen-containing material, that is, an oxide, then oxygen (O₂) may be injected into the chamber 10 in addition to the argon (Ar) gas.

The pressure inside the chamber 10, in particular, the pressure of the sputtering gas between the first target portion 100a and the second target portion 100b, may be in the range of about 0.1 mTorr to about 100 mTorr. When the pressure of the sputtering gas is higher than about 100 mTorr, the content of the sputtering gas, such as the argon (Ar) gas, within a thin film formed on the deposition target material 20 through the sputtering method may be increased, causing characteristic degradation of the thin film. When the pressure of the sputtering gas is lower than about 0.1 mTorr, it may be difficult to form plasma in the space between the first target portion 100a and the second target portion 100b, lowering a sputtering efficiency.

When power is simultaneously applied through the sputtering power supply 160 to the sputtering targets 111a and 111b facing each other, the magnetic field generated by the magnetic field generator 130 generates the sputtering plasma and confines the sputtering plasma within the space between the first target portion 100a and the second target portion 100b.

A high-density plasma may be formed from the sputtering plasma generated by magnetic field generator 130 by applying RF power to the magnetic field induction coil 150. When a magnetic field is changed by applying a potential from the RF power supply 160 to the magnetic field induction coil 150, an induced magnetic field is generated inside the chamber 10. Accordingly, a secondary induced current may be formed inside the chamber 10 by plasma ions or the like, and high-density plasma may be generated.

The plasma includes gamma-electrons, anions, cations, and the like. Electrons in the plasma form high-density plasma while doing a rotary motion along lines of magnetic force connecting the faced sputtering targets 111a and 111b of the first target portion 100a and the second target portion 100b, and the electrons maintain the high-density plasma while doing a reciprocating motion by the power applied to the sputtering targets 111a and 111b.

In other words, all electrons or ions formed within the plasma or formed by the applied power do a rotary motion along the lines of magnetic force. Likewise, charged ion particles, such as gamma-electrons, anions, and cations, also do a rotary motion along the lines of magnetic force. Therefore, charged particles having high energy of about 100 eV or more are accelerated toward the target of the opposite side, and are confined within the plasma formed in the space between the first target portion 100a and the second target portion 100b.

Such particles, which are sputtered from one of the sputtering targets 111a and 111b and have high energy of about 100 eV or more, are also accelerated toward the target of the opposite side, and do not affect the deposition target material 20 vertically disposed within the plasma formed in the space between the first target portion 100a and the second target portion 100b (i.e. disposed perpendicular to the direction of the high-energy particle movement between target portions). A thin film is formed on the deposition target material 20 by diffusion of neutral particles having relatively low energy.

Therefore, as compared with the case of using the magnetron-type sputtering apparatus in which the substrate and the target face each other, it is possible to prevent damage caused by plasma, that is, damage of the deposition target material 20 caused by collision of particles having high energy, and it is possible to form a thin film on the deposition target material 20.

Because the facing targets sputtering apparatuses 1 according to the embodiments include the magnetic field induction coil 150, high-density plasma may be formed. In addition, in the facing targets sputtering apparatuses 1 according to the embodiments, because the gas supply unit 30 is disposed so as to face the deposition target material 20, plasma ions, atoms and gases inside the chamber 10 may easily flow toward the deposition target material 20. Therefore, the facing targets sputtering apparatuses 1 according to the embodiments may prevent damage of the deposition target material 20 and may also increase the deposition rate of the thin film on the deposition target material 20.

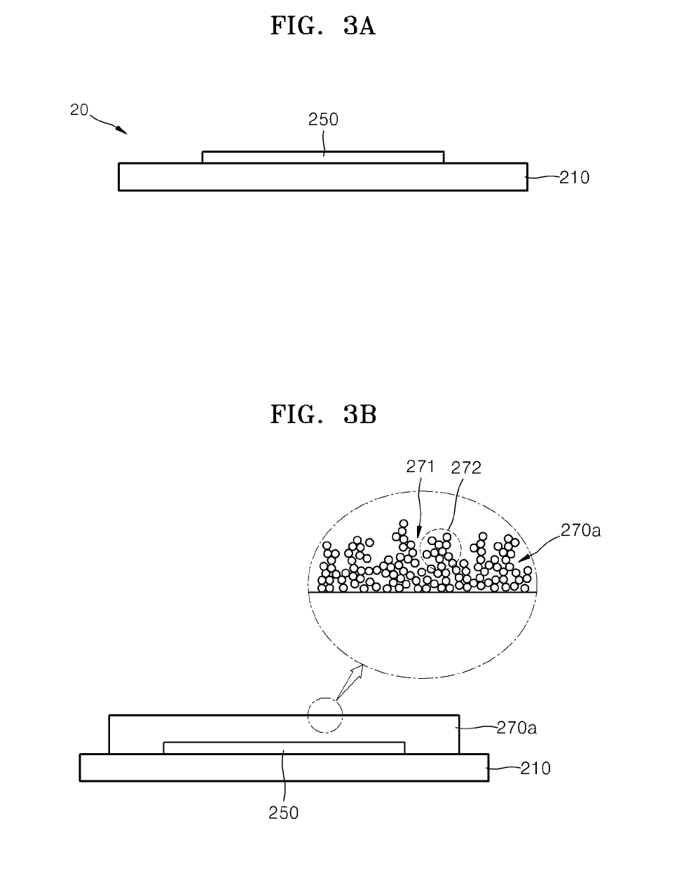

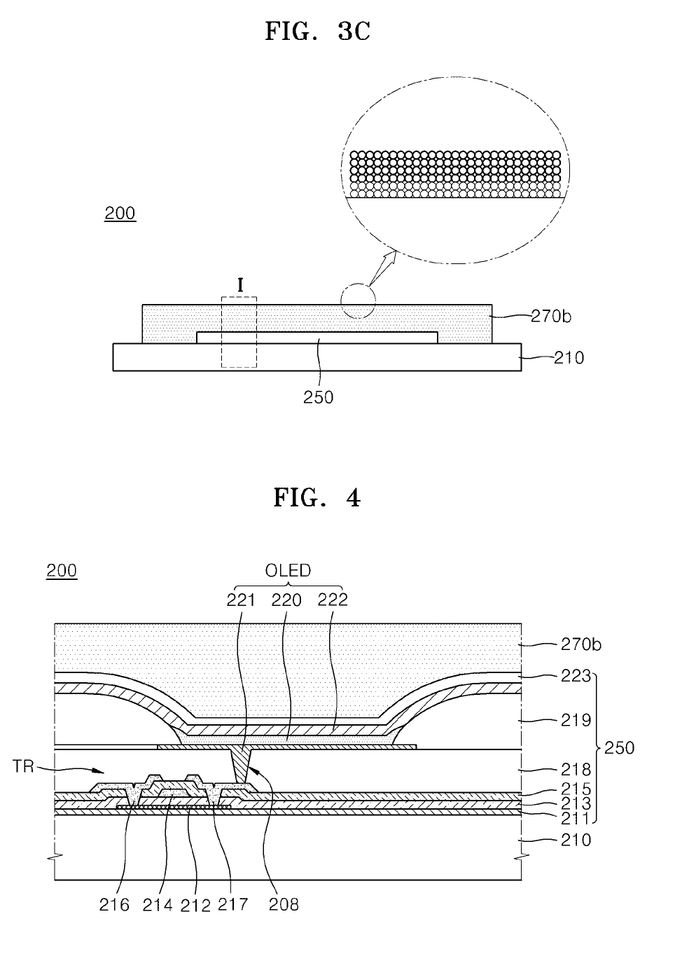

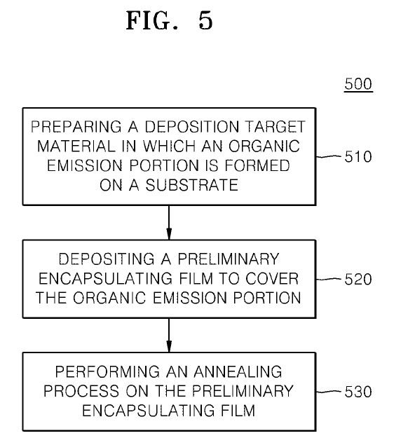

FIGS. 3A to 3C are cross-sectional views describing a method for manufacturing an organic light-emitting display apparatus 200 (as shown in FIG. 4) using the facing targets sputtering apparatus 1 according to an embodiment. FIG. 5 illustrates a process 500 for manufacuting an organic light-emitting display apparatus using the faccting targets sputtering apparatus 1 according to an embodiment.

By using the facing targets sputtering apparatus 1 according to the embodiments, various inorganic layers applicable to the organic light-emitting display apparatus 200 may be deposited. Examples of the inorganic layers may include a first electrode (221 in FIG. 4) and a second electrode (222 in FIG. 4).

An example of forming an encapsulating film 270b will be described below with respect to FIG. 3C. The encapsulating film 270b includes, as an example, tin oxide and seals an organic emission portion 250 by using the facing targets sputtering apparatus 1.

Referring to FIG. 3A at FIG. 5, a deposition target material 20 with an organic emission portion 250 formed on a substrate 210 is prepared at 510 of FIG. 5.

The substrate 210 may be a glass substrate, but is not limited thereto. The substrate 210 may be, for example, a metal or plastic substrate. The substrate 210 may be, for example, a bendable flexible substrate.

The organic emission portion 250 is provided for implementing an image. As illustrated in FIG. 4, the organic emission portion 250 includes an organic light-emitting device OLED in which a first electrode 221 and a second electrode 222 are sequentially stacked on the substrate 210. The organic emission portion 250 may include a plurality of organic light-emitting devices OLED. The organic emission portion 250 will be described below in detail with reference to FIG. 4.

Referring to FIG. 3B and FIG. 5, a preliminary encapsulating film 270a is formed on the organic emission portion 250 at 520. The preliminary encapsulating film 270a covers and seals the entire organic emission portion 250. The preliminary encapsulating film 270a includes a low temperature viscosity transition (LVT) inorganic material (hereinafter, referred to as an LVT inorganic material). The LVT inorganic material refers to an inorganic material having a low viscosity transition temperature.

The term “viscosity transition temperature” as used herein does not refer to a temperature at which a viscosity of the LVT inorganic material completely changes from solid to liquid, but refers to a minimum temperature at which fluidity may be provided to the LVT inorganic material.

As described below, the LVT inorganic material may be fluidized and then coagulated. The viscosity transition temperature of the LVT inorganic material may be lower than a metamorphic temperature of a material included in the organic emission portion 250.

The term “metamorphic temperature of the material included in the organic emission portion 250” used herein refers to a temperature that causes a chemical and/or physical metamorphosis of the material included in the organic emission portion 250. For example, the term “metamorphic temperature of the material included in the organic emission portion 250” used herein may refer to a glass transition temperature (Tg) of an organic material included in an organic emission layer 220 of the organic emission portion 250. For example, the glass transition temperature may be determined based on a result of a thermal analysis using a Thermo Gravimetric Analysis (TGA) and a Differential Scanning calorimetry (DSC) with respect to the material included in the organic emission portion 250 (N₂ atmosphere, temperature range: room temperature to 600° C. (10° C./min)-TGA, room temperature to about 400° C.-DSC, pan type: Pt pan in disposable Al Pan (TGA), disposable Al pan (DSC)), which may easily be recognized by those skilled in the art.

The metamorphic temperature of the material included in the organic emission portion 250 may exceed, for example, about 130° C., but is not limited thereto. As described above, the metamorphic temperature of the material included in the organic emission portion 250 may easily be measured through the TGA.

In some embodiments, the viscosity transition temperature of the LVT inorganic material may be about 80° C. or higher, for example, about 80° C. to about 130° C., but is not limited thereto. The viscosity transition temperature of the LVT inorganic material may be, for example, about 80° C. to about 130° C., but is not limited thereto.

The LVT inorganic material may be a single compound or a mixture of two or more kinds of compounds.

The LVT inorganic material may include, for example, tin oxide (for example, SnO or SnO₂).

When the LVT inorganic material includes SnO, the content of SnO may be about 20 wt % to about 100 wt %.

For example, the LVT inorganic material may include one or more of phosphorus oxide (for example, P₂O₅), boron phosphate (BPO₄), tin fluoride (for example, SnF₂), niobium oxide (for example, NbO), tungsten oxide (for example, WO₃), zinc oxide (for example, ZnO), and titanium oxide (for example, TiO₂), but is not limited thereto. In some embodiments, the LVT inorganic material may be a tin phosphate glass (SnO-P₂O₅).

For example, the LVT inorganic material may include, but is not limited to:
SnO,
SnO and P₂O₅;
SnO and BPO₄,
SnO, P₂O₅, and NbO; or
SnO, P₂O₅, and WO₃

For example, the LVT inorganic material may have the following composition, but is not limited thereto:
1) SnO (100 wt %);
2) SnO (80 wt %) and P₂O₅ (20 wt %); or
3) SnO (90 wt %) and BPO₄ (10 wt %)

The preliminary encapsulating film 270a may have a thickness of about 1 μm to about 30 μm, for example, about 1 μm to about 5 μm. When the thickness of the preliminary encapsulating film 270a satisfies the range of about 1 μm to about 5 μm, a flexible organic light-emitting device having a bending characteristic may be implemented.

The preliminary encapsulating film 270a may be formed using the facing targets sputtering apparatus 1 according to the embodiments. In this case, the sputtering targets 111a and 111b include the LVT inorganic material. In addition, the sputtering targets 111a and 111b may further include a conductive material for ensuring a conductivity thereof.

In some embodiments, when the preliminary encapsulating film 270a is deposited, the composition of the LVT inorganic material may be changed by adjusting an amount of oxygen injected through the gas supply unit 30.

The preliminary encapsulating film 270a may include defects such as a film-formation component 272 and a pinhole 271. The film-formation component 272 of the LVT inorganic material refers to an aggregate particle of the LVT inorganic material that does not contribute to the film formation upon the film formation of the LVT inorganic material. The pinhole 271 is a region that is empty because no LVT inorganic material is provided thereto. The generation of the film-formation component 272 of the LVT inorganic material may contribute to the formation of the pinhole 271.

Referring to FIG. 3C and FIG. 5, an annealing process may be performed to form a second encapsulating film 270b by annealing the preliminary encapsulating film 270a at 530. The annealing process may remove the defects such as the film-formation component 272 and the pinhole 271.

To perform the annealing process, an annealing temperature of the deposition target material 20 may be adjusted through the temperature controller 22 of the facing targets sputtering apparatus 1.

The annealing process is performed at a temperature equal to or higher than the viscosity transition temperature of the LVT inorganic material included in the preliminary encapsulating film 270a. The annealing process may be performed at a temperature at which the organic emission portion 250 is not damaged. For example, the annealing process may be performed by annealing the preliminary encapsulating film 270a in the range from the viscosity transition temperature of the LVT inorganic material up to the metamorphic temperature of the material included in the organic emission portion 250. The viscosity transition temperature of the LVT inorganic material is different depending upon the composition of the LVT inorganic material, and the metamorphosis of the material included in the organic emission portion 250 is different depending upon the material used in the organic emission portion 250. However, the viscosity transition temperature of the LVT inorganic material and the metamorphosis of the material included in the organic emission portion 250 may easily be recognized by those skilled in the art, depending on the composition of the LVT inorganic material and the composition of the material used in the organic emission portion 250. For example, this may be achieved by the glass transition temperature (Tg) evaluation of the organic material, which is derived from the result of the TGA with respect to the material included in the organic emission portion 250.

In some embodiments, the annealing process may be performed by annealing the preliminary encapsulating film 270a in the range of about 80° C. to about 130° C. for about one hour to about three hours (for example, at about 100° C. for about two hours), but is not limited thereto. When the temperature of the annealing process satisfies the above-described range, the fluidity of the LVT inorganic material of the preliminary encapsulating film 270a may be achieved, and the metamorphosis of the organic emission portion 250 may be prevented.

In some embodiments, the annealing process may be performed in a vacuum atmosphere or an inert gas atmosphere (for example, an N₂ atmosphere or an argon (Ar) atmosphere). In some embodiments, the annealing process may be performed within the facing targets sputtering apparatus 1. In such a case, the temperature controller 22 may maintain the annealing temperature.

In the annealing process, the fluidized LVT inorganic material may flow in and fill the pinhole (not illustrated) of the preliminary encapsulating film 270a, and the film-formation component (not illustrated) may flow in and fill the pinhole (not illustrated). As the temperature decreases after the annealing process, the fluidized LVT inorganic material changes to a solid phase again.

As a result, as illustrated in FIG. 3C, the defects of the preliminary encapsulating film 270a may be removed, and the encapsulating film 270b having a dense film quality may be formed.

FIG. 4 is a partial cross-sectional view illustrating an example of a portion I of FIG. 3C.

Referring to FIG. 4, the organic light-emitting display apparatus 200 according to an embodiment may include a substrate 210, a buffer film 211, a thin film transistor TR, an organic light-emitting device OLED, a pixel definition film 219, and an encapsulating film 270b.

The substrate 210 may be a glass substrate, but is not limited thereto. The substrate 210 may be, for example, a metal or plastic substrate. The substrate 210 may be, for example, a bendable flexible substrate.

The buffer film 211 may prevent impurity ions from being diffused into a top surface of the substrate 210, prevent penetration of moisture or outside air, and planarize the surface of the substrate 210. In some embodiments, the buffer film 211 may be formed by an inorganic material, such as, for example, silicon oxide, silicon nitride, silicon oxynitride, aluminum oxide, aluminum nitride, titanium oxide, or titanium nitride, or an organic material, such as, for example, polyimide, polyester, or acryl, or a stack thereof. The buffer film 211 is not an essential component, and may not be provided as occasion demands.

The thin film transistor TR includes an active layer 212, a gate electrode 214, and source/drain electrodes 216 and 217. A gate insulating film 213 is disposed between the gate electrode 214 and the active layer 212 in order for an insulation therebetween.

An active layer 212 may be disposed on the buffer film 211. The active layer 212 may include, for example, an inorganic semiconductor, such as amorphous silicon or poly silicon, or an organic semiconductor. In some embodiments, the active layer 212 may include an oxide semiconductor. For example, the oxide semiconductor may include an oxide of a material selected from group-12, -13 or -14 metal elements, zinc (Zn), indium (In), gallium (Ga), tin (Sn), cadmium (Cd), germanium (Ge), or hafnium (Hf), and any combinations thereof.

The gate insulating film 213 is disposed on the buffer film 211 to cover the active layer 212, and the gate electrode 214 is formed on the gate insulating film 213.

An interlayer insulating film 215 is formed on the gate insulating film 213 to cover the gate electrode 214. The source electrode 216 and the drain electrode 217 are formed on the interlayer insulating film 215, and contact the active layer 212 through contact holes.

The thin film transistor TR is not limited to the above-described structure, and various structures may also be applied to the thin film transistor. For example, the thin film transistor TR may be provided with a top gate structure, or may be provided with a bottom gate structure in which the gate electrode 214 is disposed under the active layer 212.

A pixel circuit (not illustrated) including a capacitor together with the thin film transistor TR may be formed.

A planarization film 218 covering the pixel circuit that includes the thin film transistor TR is provided on the interlayer insulating film 215. The planarization film 218 may remove a stepped portion and create a planar surface on which to form the OLED, so as to increase a luminous efficiency of the organic light-emitting device OLED provided thereon.

The planarization film 218 may include an inorganic material and/or an organic material. For example, the planarization film 218 may include a photoresist, an acryl-based polymer, a polyimide-based polymer, a polyamide-based polymer, a siloxane-based polymer, a polymer including a photosensitive acryl carboxyl group, a novolac resin, an alkali soluble resin, silicon oxide, silicon nitride, silicon oxynitride, silicon oxycarbide, silicon carbonitride, aluminum, magnesium, zinc, hafnium, zirconium, titanium, tantalum, aluminum oxide, titanium oxide, tantalum oxide, magnesium oxide, zinc oxide, hafnium oxide, zirconium oxide, or titanium oxide.

The organic light-emitting device OLED is disposed on the planarization film 218 and includes a first electrode 221, an organic emission layer 220, and a second electrode 222. The pixel definition film 219 is disposed on the planarization film 218 and the first electrode 221, and defines a pixel region and a non-pixel region.

The organic emission layer 220 may include a low-molecular-weight or high-molecular-weight organic material. In the case of using the low-molecular-weight organic material, in addition to an emission layer (EML), a hole injection layer (HIL), a hole transport layer (HTL), an electron transport layer (ETL), and an electron injection layer (EIL) may be stacked in a single or multiple structure. The low-molecular-weight organic material may be formed by a vacuum evaporation method. In this case, the emission layer may be independently formed at each of red (R), green (G) and blue (B) pixels. The hole injection layer (HIL), the hole transport layer (HTL), the electron transport layer (ETL), and the electron injection layer (EIL) may be commonly applied to the red, green and blue pixels as a common layer.

When the organic emission layer 220 is formed of a high-molecular-weight organic material, only the hole transport layer (HTL) may be included in a direction of the first electrode 221, with the emission layer as a center. The hole transport layer (HTL) may be formed on the first electrode 221 by an inkjet printing method or a spin coating method by using poly-(2,4)-ethylene-dihydroxy thiophene (PEDOT) or polyaniline (PANT). Examples of available organic materials may include high-molecular-weight organic materials based on poly-phenylenevinylene (PPV), polyfluorene, or the like. Color patterns may be formed by a general method, such as an inkjet printing method, a spin coating method, or a thermal transfer method using a laser beam.

The hole injection layer (HIL) may be formed using a phthalocyanine compound such as copper phthalocyanine, or starburst-type amine such as Tris(4-carbazoyl-9-ylphenyl)amine (TCTA), 4,4,4′-Tris(N-3-methylphenyl-N-phenylamino)triphenylamine (m-MTDATA), or 1,3,5-tris(p-N-phenyl-N-m-tolyl)phenyl)benzene (m-MTDAPB).

The hole transport layer (HTL) may be formed using N,N′-bis(3-methylphenyl)-N,N′-diphenyl[1,1-biphenyl]-4,4′-diamine (TPD), N,N′-di(naphthalene-1-yl)-N,N′-diphenyl benzidine (α-NPD), or the like.

The electron injection layer (EIL) may be formed using LiF, NaCl, CsF, Li2O, BaO, Liq, or the like.

The electron transport layer (ETL) may be formed using Alq₃.

The emission layer (EML) may include a host material and a dopant material.

Examples of the host material may include tris(8-hydroxy-quinolinato)aluminum (Alg3), 9,10-di(naphth-2-yl)anthracene (AND), 3-tert-butyl-9,10-di(naphth-2-yl)anthracene (TBADN), 4,4′-bis(2,2-diphenyl-ethene-1-yl)-4,4′-dimethylphenyl (DPVBi), 4,4′-bis(2,2-diphenyl-ethene-1-yl)-4,4′-dimethylphenyl (p-DMDPVBi), tert(9,9-diaryffluorene)s (TDAF), 2-(9,9′-spirobifluorene-2-yl)-9,9′-spirobifluorene (BSDF), 2,7-bis(9,9′-spirobifluorene-2-yl)-9,9′-spirobifluorene (TSDF), bis(9,9-diarylfluorene)s (BDAF), 4,4′-bis(2,2-diphenyl-ethene-1-yl)-4,4′-di-(tert-butyl)phenyl (p-TDPVBi), 1,3-bis(carbazol-9-yl)benzene (mCP), 1,3,5-tris(carbazol-9-yl)benzene (tCP), 4,4′,4″-tris(carbazol-9-yl)triphenylamine (TcTa), 4,4′-bis(carbazol-9-yl)biphenyl (CBP), 4,4′-bis(9-carbazolyl)-2,2′-dimethyl-biphenyl (CBDP), 4,4′-bis(carbazol-9-yl)-9,9-dimethyl-fluorene (DMFL-CBP), 4,4′-bis(carbazol-9-yl)-9,9-bis(9-phenyl-9H-carbazol)fluorene (FL-4CBP), 4,4′-bis(carbazol-9-yl)-9,9-di-tolyl-fluorene (DPFL-CBP), 9,9-bis(9-phenyl-9H-carbazol)fluorene (FL-2CBP), and the like.

Examples of the dopant material may include 4,4′-bis[4-(di-p-tolylamino)styrl]biphenyl (DPAVBi), 9,10-di(naph-2-tyl)anthracene (ADN), (3-tert-butyl-9,10-di(naph-2-tyl)anthracene (TBADN), and the like.

The first electrode 221 may be disposed on the planarization film 218 and may be electrically connected to the drain electrode 217 of the thin film transistor TR through the via hole 208 passing through the planarization film 218.

The first electrode 221 and the second electrode 222 may function as an anode electrode and a cathode electrode, respectively, but are not limited thereto. Polarities of the first electrode 221 and the second electrode 222 may be reversed.

When the first electrode 221 functions as the anode electrode, the first electrode 221 may include, for example, indium tin oxide (ITO), indium zinc oxide (IZO), zinc oxide (ZnO), or indium oxide (In2O3) having a high work function. When the organic light-emitting display apparatus 200 is a front-side emission type display apparatus that implements an image in an opposite direction to the substrate 210, the first electrode 221 may further include a reflection film including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), ytterbium (Yb), or calcium (Ca). The above-listed elements may be used solely or in combination. In addition, the first electrode 221 may be formed in a monolayer structure or a multilayer structure including the above-described metal and/or an alloy thereof. In some embodiments, the first electrode 221 is a reflective electrode and may include, for example, an ITO/Ag/ITO structure.

When the second electrode 222 functions as the cathode electrode, the second electrode 222 may be formed of a metal, such as, for example, Ag, Mg, Al, Pt, Pd, Au, Ni, Nd, Ir, Cr, Li, or Ca. When the organic light-emitting display apparatus 200 is the front-side emission type display apparatus, the second electrode 222 is required to transmit light. In some embodiments, the second electrode 222 may include a transparent conductive metal oxide, such as, for example, ITO, IZO, ZTO, ZnO, or In2O3.

In other embodiments, the second electrode 222 may be provided with a thin film including, for example, at least one material selected from Li, Ca, LiF/Ca, LiF/AI, Al, Ag, Mg, or Yb. For example, the second electrode 222 may be formed in a monolayer or a stacked structure of Mg:Ag, Ag:Yb and/or Ag. Unlike the first electrode 221, the second electrode 222 may be formed such that a common voltage is applied to all pixels.

The pixel definition film 219 includes an opening exposing the first electrode 221, and defines a pixel region and a non-pixel region of the organic light-emitting device. Although only one opening is illustrated, the pixel definition film 219 may include a plurality of openings. The first electrode 221, the organic emission layer 220, and the second electrode 222 are sequentially stacked within the opening of the pixel definition film 219, and the organic emission layer 222 is configured to emit light. In other words, a region where the pixel definition film 219 is formed becomes a substantial non-pixel region, and the opening of the pixel definition film 219 becomes a substantial pixel region.

When the plurality of openings are formed, the organic light-emitting display apparatus 200 may include a plurality of organic light-emitting devices. A single pixel may be formed in each organic light-emitting device, and a red color, a green color, a blue color, or a white color may be implemented at each pixel.

However, the embodiments are not limited thereto. The organic emission layer 220 may be commonly formed on the entire planarization film 218, without regard to the position of the pixel. The organic emission layer 220 may be formed by vertically stacking or combining layers including light-emitting materials that emit red light, green light, and blue light. A combination of other colors may also be applied as long as emission of white light is possible. In addition, the display apparatus may further include a color filter or a color conversion layer converting the emitted white light into a predetermined color.

A protection layer 223 may be disposed on the organic light-emitting device OLED and the pixel definition film 219, and may cover and protect the organic light-emitting device OLED. The protection layer 223 may include an inorganic insulating film and/or an organic insulating film. The inorganic insulating film may include, for example, SiO₂, SiNx, SiON, Al₂O₃, TiO₂, Ta₂O₅, HfO₂, ZrO₂, BST, or PZT. The organic insulating film may include, for example, a general-purpose polymer (PMMA, PS), a polymer derivative having a phenol-based group, an acryl-based polymer, an imide-based polymer, arylether-based polymer, an amide-based polymer, a fluorine-based polymer, a p-xylene-based polymer, a vinylalcohol-based polymer, and a blend thereof. The protection layer 223 may be deposited by various deposition methods, such as plasma enhanced chemical vapor deposition (PECVD), atmospheric pressure CVD (APCVD), or low pressure CVD (LPCVD).

As described above, the encapsulating film 270b is disposed on the organic light-emitting device and prevents external oxygen or moisture from being penetrated into the organic light-emitting device. Because the encapsulating film 270b includes an LVT material, the metamorphosis of the organic light-emitting device may be minimized during sealing.

In addition, because the encapsulating film 270b is formed by the facing targets sputtering apparatus 1 according to the embodiments, damage to the organic emission portion 250 may be prevented during the forming of the encapsulating film 270b. Moreover, because the deposition rate of the encapsulating film 270b is improved, the process time may be reduced.

As described above, according to the one or more of the above embodiments, the facing targets sputtering apparatus includes the magnetic field induction coil, and thus, high-density plasma may be formed. Furthermore, in the facing targets sputtering apparatuses according to the embodiments, because the gas supply unit is disposed so as to face the deposition target material, plasma ions, atoms and gases inside the chamber may easily flow in a direction toward the deposition target material.

Therefore, the facing targets sputtering apparatuses according to the embodiments may prevent damage of the deposition target material and increase the deposition rate of the thin film on the deposition target material.

It should be understood that the example embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the present invention as defined by the following claims.

What is claimed is:

1. A sputtering apparatus comprising:
a chamber including a mounting portion configured to hold a deposition target material;
a gas supply unit that faces the mounting portion and supplies gas to the chamber;
a first target portion and a second target portion that face each other within the chamber; and
a magnetic field induction coil that surrounds an outside of the chamber.

2. The sputtering apparatus of claim 1, wherein the first target portion and the second target portion are separated from each other, and the gas supply unit is positioned so that gas supplied from the gas supply unit passes through a gap between the first target portion and the second target portion.

3. The sputtering apparatus of claim 1, wherein the magnetic field induction coil is provided at a position corresponding to positions of the first target portion and the second target portion.

4. The sputtering apparatus of claim 1, wherein each of the first target portion and the second target portion comprises:
a target plate on which a sputtering target is mounted;
a yoke disposed on a rear surface of the target plate; and
a magnetic field generator disposed on a rear surface of the yoke.

5. The sputtering apparatus of claim 4, wherein the magnetic field generator comprises:
a first magnetic field generator; and
a second magnetic field generator,
wherein the first magnetic field generator and the second magnetic field generator are disposed at both ends of the yoke.

6. The sputtering apparatus of claim 5, wherein the magnetic field generator further comprises a third magnetic field generator,
wherein the third magnetic field generator is disposed in a center of the target plate and generates a magnetic field in an opposite direction to a magnetic field generated by the first and second magnetic field generators.

7. The sputtering apparatus of claim 4, wherein the yoke is made of a ferromagnetic material or a paramagnetic material.

8. The sputtering apparatus of claim 4, wherein the yoke is made of one of iron, cobalt, nickel, and an alloy thereof.

9. The sputtering apparatus of claim 1, wherein a pressure of sputtering gas between the first target portion and the second target portion is in the range of about 0.1 mTorr to about 100 mTorr.

10. The sputtering apparatus of claim 1, wherein the mounting portion further comprises a temperature controller that controls a temperature of the deposition target material.

11. An organic light-emitting display apparatus comprising:
a substrate;
an organic emission portion including an organic light-emitting device on the substrate; and
an encapsulating film that seals the organic emission portion, the encapsulating film being formed using the sputtering apparatus of any one of claims 1 to 10.

12. The organic light-emitting display apparatus of claim 11, wherein the encapsulating film comprises a low temperature viscosity transition (LVT) inorganic material.

13. The organic light-emitting display apparatus of claim 11, wherein the encapsulating film comprises tin oxide.

14. The organic light-emitting display apparatus of claim 11, wherein the encapsulating film comprises an low temperature viscosity transition (LVT) inorganic material, and a viscosity transition temperature of the LVT inorganic material is lower than a metamorphic temperature of the organic emission portion.

15. A method for manufacturing an organic light-emitting display apparatus, the method comprising:
preparing a deposition target material in which an organic emission portion is formed on a substrate; and
forming an encapsulating film to seal the organic emission portion by using a sputtering apparatus,
wherein the sputtering apparatus includes:
a chamber including a mounting portion holding the deposition target material;
a gas supply unit facing the mounting portion and supplying gas to the chamber;
a first target portion and a second target portion facing each other within the chamber; and
a magnetic field induction coil surrounding an outside of the chamber.

16. The method of claim 15, wherein the forming of the encapsulating film comprises:
depositing a preliminary encapsulating film to cover the organic emission portion; and
performing an annealing process on the preliminary encapsulating film.

17. The method of claim 15, wherein the encapsulating film comprises a low temperature viscosity transition (LVT) inorganic material.

18. The method of claim 15, wherein the sputtering apparatus further comprises a temperature controller that controls a temperature of the deposition target material, and an annealing process is performed on the encapsulating film by the temperature controller.

19. The method of claim 18, wherein the annealing process is performed at a lower temperature than a metamorphic temperature of a material included in the organic emission portion.

20. The method of claim 18, wherein the annealing process is performed under a vacuum atmosphere or an inert gas atmosphere.
